(19) United States
(12) Patent Application Publication
(10) Pub. No.: US 2006/0041807 A1
(43) Pub. Date: Feb. 23, 2006

(54) Integrated circuit

(75) Inventor: Hiroaki Terai, Kanagawa (JP)

Correspondence Address: FOLEY AND LARDNER LLP;SUITE 500, 3000 K STREET NW, WASHINGTON, DC, 20007, US

(73) Assignee: NEC Electronics Corporation

(21) Appl. No.: 11/208,617

(22) Filed: Aug. 23, 2005

(30) Foreign Application Priority Data
Aug. 23, 2004 (JP) 2004-242779

(51) Int. Cl. G01R 31/28

(52) U.S. Cl. 714/733

(57) ABSTRACT

An integrated circuit has a memory block including a RAM macro, a first scan circuit and a second scan circuit having a plurality of SFFs, and a serial access memory BIST circuit. The first scan circuit has an input scan FF group capable of supplying data to the memory block and the second scan circuit has an output scan FF group capable of receiving data from the memory block. In a first test mode, a normal scan test is performed. In a second test mode, the serial access memory BIST circuit outputs a BIST signal serially, and a selector selects and supplies the BIST signal to the input scan FF group, thereby testing the memory block.

### BACKGROUND OF THE INVENTION

1. Field of the Invention

The present invention relates to an integrated circuit having a memory macro and, particularly, to an integrated circuit capable of implementing a scan test and Built-In Self Test (BIST) on a memory macro.

2. Description of Related Art

A scan path test is known as a technique for testing a large-scale digital logic circuit. This test technique inputs test data to a scan chain composed of a plurality of scan flip-flops (SFFs) connected in series and shifts the data sequentially, thereby testing a logic circuit module.

Japanese Unexamined Patent Publication No. 2000-009806, for example, describes a basic scan test technique that tests a logic circuit module by using a scan chain. It also describes a technique for making a test more efficient by externally inputting a scan pattern to the middle of the scan chain or externally retrieving the output of the scan test from the middle of the scan chain.

Further, Japanese Unexamined Patent Publication No. 2004-206751 describes a technique that combines the scan test and a BIST. In the combination of the scan test and BIST, the scan test allows checking the operation with a high-speed actual operation clock frequency while the BIST allows testing the write and read operation in each address of a Random Access Memory (RAM) macro or a RAM main memory.

FIG. 8 is a block diagram showing an example of a conventional integrated circuit to combine a scan test and BIST. As shown in FIG. 8, an integrated circuit 101 has a memory block 110, scan circuits 107 and 108, and a parallel access memory BIST circuit 103.

The memory block 110 has a RAM macro 102, an input combinational circuit 105, an output combinational circuit 106, and a selector group 111. The input combinational circuit 105 is placed in the input side of the RAM macro 102, and the output combinational circuit 106 is placed in the output side of the RAM macro 102. The selector group 111 selects a BIST signal or a test signal from the input combinational circuit 105 and outputs the selected signal to the RAM macro 102.

The RAM macro 102 has a memory cell and a read/write control section. The memory cell stores data and the read/write control section controls writing or reading of data to or from the memory cell. The RAM macro 102 receives a write address, write data and a write control signal when writing data and receives a read address and a read control signal when reading data. The RAM macro 102 thereby allows writing or reading data individually.

The scan circuits 107 and 108 are each formed of a scan chain that is composed of a plurality of SFFs 109 connected in series. They can shift a test signal for a scan test from a SFF 109 in the previous stage to a SFF 109 in the subsequent stage.

The parallel access memory BIST 103 supplies a BIST signal in parallel to the RAM macro 102.

The integrated circuit 101 has a first test mode, a second test mode, and a third test mode. The first test mode tests a combinational circuit, not shown, which is different from the combinational circuits 105 and 106 by using the scan circuits 107 and 108. The second test mode tests the RAM macro 102 with the scan circuits 107 and 108. The third test mode executes a BIST with the parallel access memory BIST circuit.

The selector group 111 is composed of a plurality of selectors respectively connected to a plurality of inputs of the RAM macro 102. The selector group 111 is switched and controlled by a selection signal SEL between the second and third test modes. The second and third test modes are thereby switched and implemented.

Specifically, the selector group 111 selects a test signal from the combinational circuit 105 and inputs it to the RAM macro 102 in the second test mode. In the third test mode, the selector group 111 selects a BIST signal generated by the BIST circuit 103 and inputs it to the RAM macro 102.

The scan circuit 107 has a scan input terminal (SC_{IN}) 121, a scan output terminal (SC_{OUT}) 122, and SFFs 109. The scan input terminal (SC_{IN}) 121 is a terminal for supplying a test signal for a scan test, and the scan output terminal (SC_{OUT}) 122 is a terminal for outputting a test result. Of the plurality of the SFFs 109, predetermined SFFs 109 are connected to the input combinational circuit 105.

Similarly, the scan circuit 108 has a scan input terminal (SC_{IN}) 131, a scan output terminal (SC_{OUT}) 132, and SFFs 109, and predetermined SFFs 109 are connected to the output combinational circuit 106.

The SFFs 109 that constitute the scan circuits 107 and 108 sequentially shift a test signal from a SFF 109 in the previous stage to a SFF 109 in the subsequent stage by the shift operation during the scan test.

The parallel access memory BIST circuit 103 generates a BIST signal to be supplied to the RAM macro 102 in the third test mode. The parallel access memory BIST circuit 103 then outputs the generated BIST signal in parallel to the RAM macro 102 through the selector group 111. If the BIST signal contains a read command for reading data form the RAM macro 102, the parallel access memory BIST circuit 103 receives a result signal (test data) in parallel. Then, the parallel access memory BIST circuit 103 compares the result signal with an expected value to see if they match and outputs a matching result.

The test operation in the integrated circuit 101 having the above configuration is described hereinafter. As described above, the integrated circuit 101 has the first to third test modes. In the first test mode, it conducts a test on a combinational circuit which is not shown and different from the combinational circuits 105 and 106 by shifting test data in the scan chain.

In the second test mode, a logic value “0”, for example, is input to a selection signal input SEL of the selector group 111. Each selector of the selector group 111 is thereby set to supply the data from the combinational circuit 105 to the RAM macro 102.

The SFF 109 is switched between shift mode and capture mode according to the logic value of a scan mode control (SMC) signal. In the shift mode, the SFF 109 outputs the data which it retains to the SFF 109 in the subsequent stage, thereby setting the data to a prescribed SFF 109. In the capture mode, the SFF 109 outputs data to the combinational circuit 105 so as to write test data to the RAM macro 102.

Similarly, the SFF 109 reads out the test data that has been written to the RAM macro 102. The test data is read out from the RAM macro 102 through the combinational circuit 106 to the SFF 109 as a result signal. The result signal is then output to the outside of the integrated circuit through the scan output terminal SC_{OUT} 132. An external test unit, which is not shown, compares the result signal with an expected value. If they match, it is determined that read/write operation is performed normally at an actual operation frequency of the integrated circuit 101 in the tested address of the memory block 110 that includes the combinational circuit 105, the RAM macro 102, and the combinational circuit 106.

In the third test mode, a logic value “1”, for example, is input to the selection signal input SEL of the selector group 111. Each selector of the selector group 111 is thereby set to output the BIST signal from the parallel access memory BIST circuit 103 to the RAM macro 102.

The operation test of the RAM macro 102 with use of the parallel access memory BIST circuit 103 is performed by writing test data and then reading it out. When writing data, the parallel access memory BIST circuit 103 generates a BIST signal containing a write address, write data (test data) and a write control signal and supplies it to the selector group 111. When reading data, the parallel access memory BIST circuit 103 generates a BIST signal containing a read address and a read control signal and supplies it to the selector group 111. With these BIST signals, the parallel access memory BIST circuit 103 writes test data to the RAM macro 102, then reads the written test data therefrom, and compares the acquired test data with an expected value, thereby testing the RAM macro 102.

Since the integrated circuit 101 has the parallel access memory BIST circuit 103, it is possible to generate a memory address to be tested and test data inside the integrated circuit 101. It is also possible to perform the comparison with an expected value inside the integrated circuit 101. Further, with the scan circuits, it is possible to test the memory clock 110 by using a clock having an actual operation frequency of the integrated circuit 101.

The technique disclosed in Japanese Unexamined Patent Publication No. 2004-206751 places a built-in parallel access memory BIST circuit to input a read/write BIST signal to the RAM macro 102. This enables a unit test on all address about the operation of a RAM macro. However, the present invention has recognized that this technique has the following problem. In order to test the operation of the memory block 110 that has the combinational circuits in the previous and subsequent stages of the RAM macro with an actual operation clock frequency, it is necessary to set data to be a prescribed write command or read command to the scan circuits 107 and 108 from an external terminal through the scan chain each time testing one address, which requires a large scan pattern. Thus, it takes very long time to perform a scan test on a number of addresses of a memory block, thus being impractical. It is therefore needed to test only some of addresses in application to actual products, which hinders to achieve a high fault detection rate. Thus, since the test on a path of the memory block 110 that includes the RAM macro 102 and the combinational circuits in the previous and subsequent stages of the RAM macro 102 requires a long scan pattern and a long test time, the test can be performed on only some of addresses in actual application.

### SUMMARY OF THE INVENTION

According to an aspect of the present invention, there is provided an integrated circuit that has a memory block including a memory macro, a scan circuit including a plurality of scan cells forming a scan path, and a Built-In Self Test (BIST) circuit generating a BIST signal, receiving a result signal indicating a test result of the memory block, and determining if the result signal matches an expected value. In this integrated circuit, the plurality of scan cells include an input scan cell group capable of supplying data to the memory block and an output scan cell group capable of receiving data from the memory block. Further, each scan cell of the input scan cell group receives a scan test signal from a scan cell of a previous stage in a first test mode and receives the BIST signal in a second test mode, and each scan cell of the output scan cell group receives a scan test signal from a scan cell of a previous stage in the first test mode and receives the result signal from the memory block in the second test mode.

Since the input scan cell group receives the BIST signal from the BIST circuit to perform a BIST on the memory macro, the present invention allows the test on the memory macro to be performed with an actual operation clock frequency in a short time.

Further, the integrated circuit may have a memory block that includes a combinational circuit in previous and/or subsequent stages of the RAM macro in this invention. This configuration also allows a test on a memory block to be performed efficiently with an actual operation clock frequency in a short time.

### BRIEF DESCRIPTION OF THE DRAWINGS

The above and other objects, advantages and features of the present invention will be more apparent from the following description taken in conjunction with the accompanying drawings, in which:

FIG. 1 is a block diagram of an integrated circuit according to a first embodiment of the invention;

FIG. 2 is a view showing a detail of a part of a scan chain;

FIG. 3 is a flowchart showing a test method in a second test mode of the integrated circuit according to the first embodiment of the invention;

FIGS. 4A and 4B are waveform charts showing a SMC signal and a clock CK that are input to a SFF of the integrated circuit according to the first embodiment of the invention in the second test mode;

FIG. 5 is a block diagram of an integrated circuit according to a second embodiment of the invention;

FIG. 6 is a block diagram of an integrated circuit according to a third embodiment of the invention;

FIG. 7 is a view showing a detail of a part of a scan chain according to the third embodiment of the invention; and

FIG. 8 is a block diagram of a conventional semiconductor device.

### DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposed.

Embodiments of the present invention are described hereinafter in detail with reference to the drawings. The following embodiments describe the case of applying the present invention to an integrated circuit having a RAM macro.

### First Embodiment

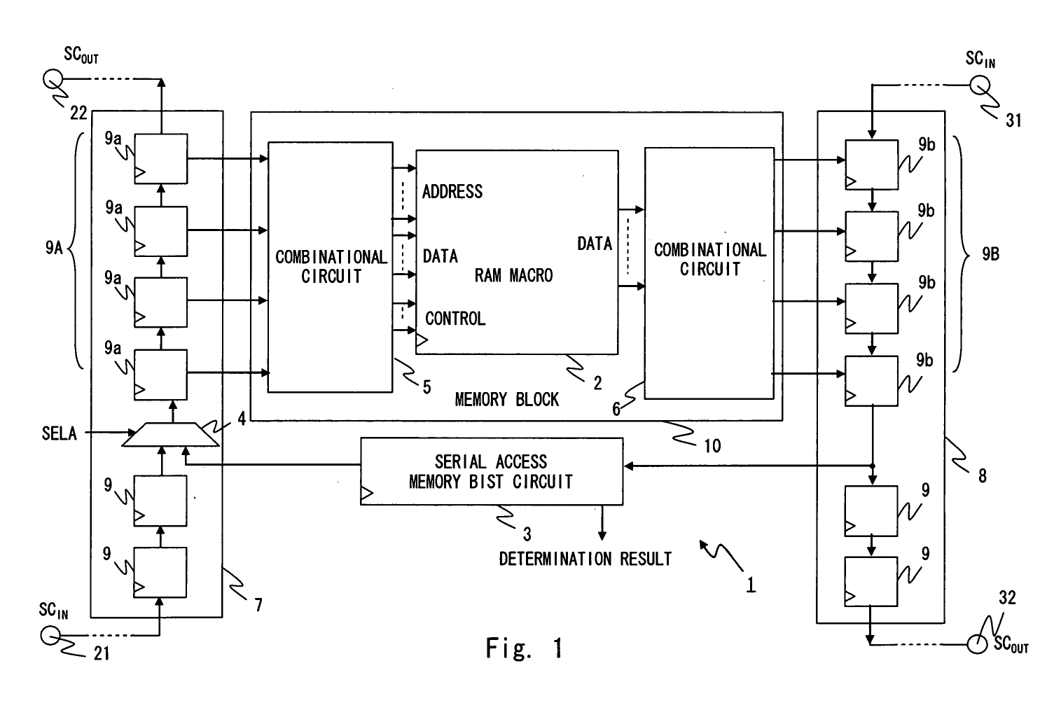

FIG. 1 is a block diagram showing an integrated circuit of the first embodiment of the invention. As shown in FIG. 1, an integrated circuit 1 has a memory block 10, a serial access memory BIST circuit 3, a first scan circuit 7, and a second scan circuit 8.

The memory block 10 has a RAM macro 2 which is a type of a memory macro and one or a plurality of combinational circuits that are placed at the periphery of the RAM macro 2. The memory block 10 in this embodiment has a first combinational circuit 5 and a second combinational circuit 6. The first combinational circuit 5 is placed between the first scan circuit 7 and the input side of the RAM macro 2. The second combinational circuit 6 is placed between the output side of the RAM macro 2 and the second scan circuit 8.

The integrated circuit 1 of this embodiment has a first test mode and a second test mode in addition to a normal operation mode. In the first test mode, the first scan circuit 7 and the second scan circuit 8 perform a scan test on a combinational circuit which is not shown and different from the combinational circuits 5 and 6 in the integrated circuit 1. In the second test mode, the serial access memory BIST circuit 3 performs a BIST on the memory block 10.

The first scan circuit 7 and the second scan circuit 8 are each formed of a scan chain that is composed of a plurality of SFFs as scan cells connected in series to form a scan path. In the first test mode, a test signal for scan test (scan test pattern) is input to the first scan circuit 7 through a scan input terminal (SC_{IN}) 21. A test result is output through a scan output terminal (SC_{OUT}) 22. The test signal is also input to the second scan circuit 8 through a scan input terminal (SC_{IN}) 31, and a test result is output through a scan output terminal (SC_{OUT}) 32. The scan test is performed by observing the outputs.

Though this embodiment describes that the first scan circuit 7 in the input side and the second scan circuit 8 in the output side form different scan chains, it may be a single scan chain from the scan input terminal 21 to the scan output terminal 32.

The plurality of SFFs 9 that constitute the first scan circuit 7 include an input SFF group 9A. The input SFF group 9A is composed of SFFs that are connected to the combinational circuit 5. The plurality of SFFs 9 that constitute the second scan circuit 8 include an output SFF group 9B. The output SFF group 9B is composed of SFFs that are connected to the combinational circuit 6. The SFFs 9 of the first scan circuit 7 which constitute the input SFF group 9A are referred to hereinafter as SFF9a in order to distinguish them from the other SFFs. Similarly, the SFFs 9 of the second scan circuit 8 which constitute the output SFF group 9B are referred to hereinafter as SFF 9b. In the example of FIG. 1, the input SFF group 9A has four SFFs 9a and the output SFF group 9B has four SFFs 9b.

In the integrated circuit 1 of this embodiment, the selector 4 is placed in the middle of the scan chain of the first scan circuit 7 in an earlier stage than the input SFF group 9A. The input of the selector 4 receives a scan input signal and a serial access BIST signal. The scan input signal is supplied from a SFF 9 in the previous stage. The serial access BIST signal is supplied from the serial access memory BIST circuit 3. The serial access BIST signal is a test signal for testing the RAM macro 2, which is generated in the serial access memory BIST circuit 3. The selector 4 further receives a first selection signal SELA as a control signal. The first selection signal SELA has a different logic level between the first test mode and the second test mode.

The selector 4 selects and outputs either the scan input signal or the serial access memory BIST signal according to the first control signal.

The selector 4 selectively outputs the scan input signal or the BIST signal in accordance with the logic level of the first selection signal SELA. Specifically, in the first test mode, the selector 4 receives the first selection signal SELA having a logic level “0”, for example, to select the scan input signal from the SFF 9 or 9a in the previous stage and output it to the SFF 9a in the subsequent stage. In the second test mode, it receives the first selection signal SELA having a logic level “1”, for example, to select the BIST signal from the parallel access memory BIST circuit 3 and output it to the corresponding SFF 9a.

Preferably, the selector 4 is placed between the SFF 9 and the input SFF group 9A in order to set the serial access BIST signal to the input SFF group 9A in a short time.

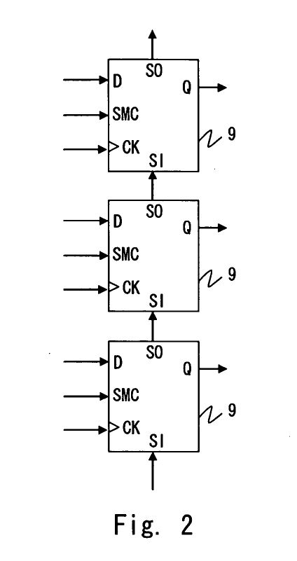

The scan chain of the first scan circuit 7 and the second scan circuit 8 is described hereinafter. FIG. 2 shows a detail of a part of the scan chain. The SFFs 9, 9a and 9b have the same configuration as a normal SFF. Each of the SFFs 9, 9a and 9b has a clock input terminal CK, a data input terminal D, a scan input terminal SI, a scan output terminal SO, an output terminal Q, and a scan mode control (SMC) terminal. They have a shfit mode and a capture mode.

The clock input terminal CK receives a clock. The data input terminal D receives data in normal operation. The scan input terminal SI receives a test signal during the shift mode. The scan output terminal SO and the output terminal Q output the data retained in the SFF 9a at the timing of the clock CK. The SMC signal is a signal to select between the shift mode that outputs the retained data through the scan output terminal SO and the capture mode that outputs the data through the output terminal Q. The SMC signal in the normal operation mode has the same logic level as in the capture mode.

In each of the SFFs 9, 9a and 9b, the scan input terminal SI is connected to the scan output terminal SO of the SFF 9 in the previous stage and the scan output terminal SO is connected to the scan input terminal SI of the subsequent stage.

The data output terminal Q of the SFF 9a is connected to the first combinational circuit 5. The data input terminal D of the SFF 9b is connected to the second combinational circuit 6. The SFFs 9, 9a, and 9b shift data from the SFF in the previous stage to the SFF in the subsequent stage in the shift mode. In the capture mode, the SFF 9a supplies the acquired data to the first combinational circuit 5 through the data output terminal Q, and the SFF 9b receives the data from the second combinational circuit 6 through the data input terminal D.

The serial access memory BIST circuit 3 is connected to the selector 4 to supply the BIST signal serially to the input SFF group 9A. The serial access memory BIST circuit 3 is connected to the output of the output SFF group 9B or the output of the SFF 9 in the later stage in the second scan circuit 8. The output SFF group 9B receives a result signal from the memory block 10 and transfers it to the serial access memory BIST circuit 3. The serial access memory BIST circuit 3 is preferably connected to the output of the SFF 9b in the final stage of the output SFF group 9B in the scan chain of the second scan circuit 8 in order to receive the result signal in a shorter time. However, the serial access memory BIST circuit 3 may be connected to another place as long as it can receive a result signal input to the output SFF group 9B. For example, the output of the SFF 9 in the subsequent stage of the output SFF group 9B may be input to the serial access memory BIST circuit 3.

In the integrated circuit 1 of this configuration, a known scan test is performed in the first test mode. The first scan circuit 7 is used as a part of the scan chain between the scan input terminal 21 and the scan output terminal 22 of the integrated circuit 1, and the second scan circuit 8 is used as a part of the scan chain between the scan input terminal 31 and the scan output terminal 32.

In the second test mode, the serial access memory BIST circuit 3 generates and outputs a BIST signal. The BIST signal serves as a write command for writing data to a tested address of the RAM macro 2. The BIST signal is selectively supplied to the input SFF group 9A by the selector 4. The BIST signal is then supplied to the RAM macro 2 through the combinational circuit 5 so that test data is written to the tested address of the RAM macro 2. After that, the serial access memory BIST circuit 3 generates and outputs a BIST signal that serves as a read command for reading data from the same address as the tested address. The BIST signal is also selectively supplied to the input SFF group 9A by each selector 4. The BIST signal is then supplied to the RAM macro 2 through the combinational circuit 5 so as to control the RAM macro 2 to read the test data from the tested address. The acquired test data is supplied to the combinational circuit 6 where logic operation is performed to obtain a result signal. The result signal is supplied to the output SFF group 9B and then serially transferred from the second scan circuit 8 to the serial access memory BIST circuit 3. The serial access memory BIST circuit 3 compares the read test data, which is the result signal after the logic operation in the output combinational circuit 6, with an expected value to see if they match.

In the second test mode, the SFFs 9, 9a and 9b are in the shift mode during the period when the BIST signal is set to the input SFF group 9A and when the output SFF group 9B transfers the received result signal to the serial access memory BIST circuit 3, and perform shift operation in synchronization with a clock. In the shift mode, the clock CK may have a different frequency from an actual operation frequency of the integrated circuit.

Further, the period when outputting the BIST signal set to the input SFF group 9A and when reading the test data from the RAM macro 2 is in the capture mode to perform the operation of outputting the acquired BIST signal or acquiring the result signal with an actual operation frequency.

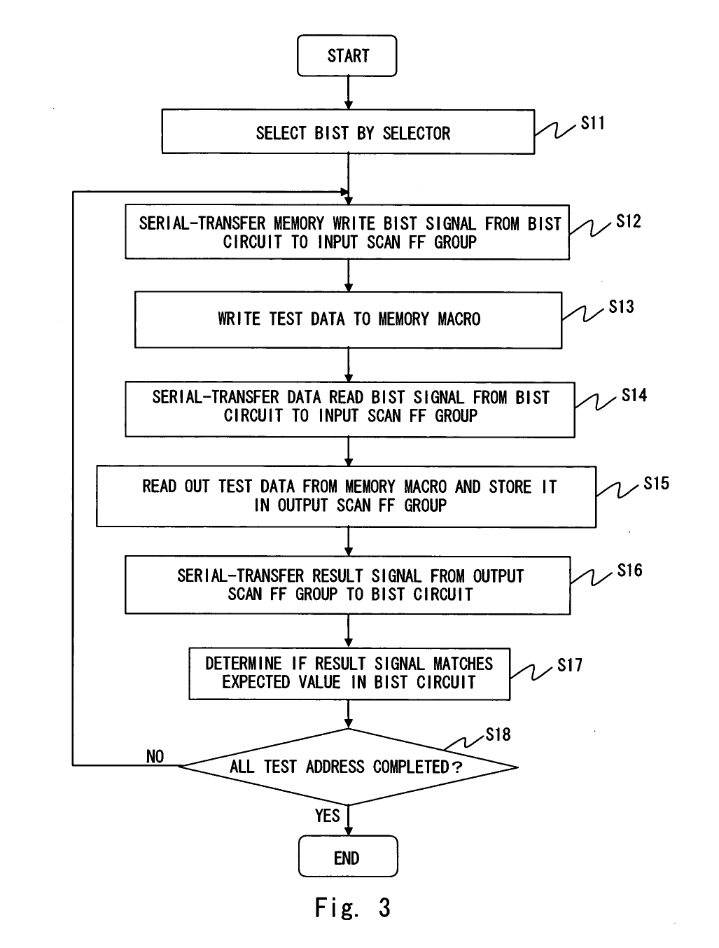

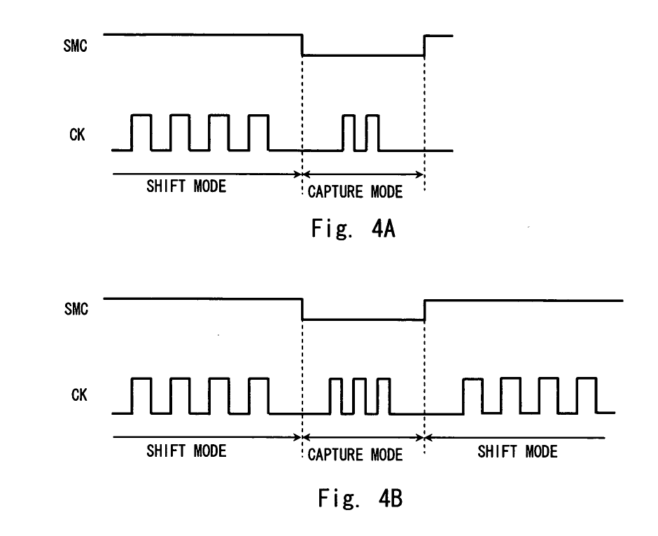

The test method of the serial access memory BIST circuit 3 in the second test mode is described hereinafter in detail with reference to FIGS. 3 and 4. FIG. 3 is a flowchart showing the test method of the integrated circuit 1 in the second test mode. FIGS. 4A and 4B are waveform charts showing the SMC signal and the clock CK input to the SFF 9a in the second test mode. In the second test mode, the selector 4 receives a first selection signal SELA having a logic level “1”, for example, so as to select the BIST signal from the serial access memory BIST circuit 3 (S11).

First, the serial access memory BIST circuit 3 generates a BIST signal that serves as a write command. The BIST signal to be a write command is serially output from the serial access memory BIST circuit 3, and the selector 4 selectively supplies the BIST signal to the input SFF group 9A of the scan circuit 7 (S12). The input SFF group 9A shifts and transfers the BIST signal sequentially from the SFF 9a in the initial stage to the SFF 9a in the next stage in synchronization with a clock. During the shift mode, the clock may have a lower frequency than an actual operation clock frequency as shown in FIG. 4A.

The SFFs 9, 9a and 9b are the same as normal SFFs as described above and perform the shift operation in synchronization with the clock CK by setting the SMC signal to a logic value “1”, for example, to enter the shift mode. By supplying a predetermined number of clock pulses to the scan circuit 7, the BIST signal of a write command is stored into the input SFF group 9A.

Then, the SMC signal is changed to the logic level “0”, for example, to enter the capture mode as shown in FIG. 4A. After that, two clock pulses of the clock CK are supplied to the integrated circuit 1 at an actual operation frequency. In synchronization with the rising edge of the first pulse, the input SFF group 9A outputs a BIST signal for write command to the combinational circuit 5. The combinational circuit 5 performs logic operation on the BIST signal to convert it into a write command composed of a write address, write data (test data) and a write control signal and supplies the write command to the RAM macro 2, thereby writing the test data (S13).

Then, the SMC signal is set back to the shift mode as shown in FIG. 4B so that the serial access memory BIST circuit 3 generates a read command. The read command is serially output as a serial access BIST signal as in the step S12, and the selector 4 selects and transfers this signal to the input SFF group 9A in the scan circuit 7 (S14).

After that, as shown in FIG. 4B, the SMC signal is again changed to the capture mode as shown in FIG. 4B, and three clock pulses of the clock CK is supplied to the integrated circuit 1 at an actual operation frequency. In synchronization with the rising edge of the first clock pulse, the input SFF group 9A outputs a BIST signal for read command to the combinational circuit 5. The BIST signal is supplied to the RAM macro 2 through the combinational circuit 5. At this time, the combinational circuit 5 performs logic operation on the BIST signal to convert it into a read command composed of a read address and a read control signal. In synchronization of the rising edge of the next clock pulse, the test data that has been written in the step S13 is read out. The acquired test data is supplied to the combinational circuit 6 where the logic operation is performed thereon, and the data is stored as a test result signal of the memory block 10 into the SFFs 9b that constitute the output SFF group 9B in the second scan circuit 8 until the falling edge of the third clock pulse (S15).

Then, the SMC signal is again set to the shift mode as shown in FIG. 4B to supply the clock CK. The result signal is thereby shifted through the SFFs 9b and serially transmitted to the serial access memory BIST circuit 3 (S16). The result signal is obtained by performing the logic operation on the test data that has been read out from the memory block 10 in the second combinational circuit 6.

The serial access memory BIST circuit 3 compares the acquired result signal with an expected value to see if they match. If they match, it outputs a matching signal with a predetermined logic level, which may be a logic value 1, for example (S17). The matching signal may be output outside. Further, if the result signal and the expected value do not match, the address may be stored in a register, not shown, placed in the integrated circuit 1.

The serial access memory BIST circuit 3 determines if the test has been completed on all of predetermined test addresses. If all the predetermined addresses have been tested, the test by the serial access memory BIST circuit 3 ends. At this time, the test end information may be sent to the outside of the integrated circuit 1. If, on the other hand, an untested address still remains, the step S12 and the subsequent steps are performed on the next test address (S18).

As described above, in this embodiment, the serial access memory BIST circuit 3 generates a serial BIST signal to be converted into a write or read command to the RAM macro 2. The serial BIST signal can be selectively supplied to the input SFF group 9A by the selector 4 that is placed in the middle of the scan circuit 7. The input SFF group 9A temporarily stores the serial access BIST signal and then supplies the BIST signal through the combinational circuit 5. It is thereby possible to perform the operation of writing the test data to the RAM macro 2 in the memory block 10 in synchronization with the clock at an actual operation frequency.

Further, the input SFF group 9A temporarily stores the BIST signal to be converted into a read command to the RAM macro 2 in the input SFF group 9A and then supplies it to the RAM macro 2 in the memory block 10 through the combinational circuit 5. It is thereby possible to perform the operation of reading the test data from the RAM macro 2 in synchronization with the clock at an actual operation frequency.

Further, the output SFF group 9B shifts the result signal that is temporarily stored therein sequentially to the SFF in the next stage and thereby transfers it to the serial access memory BIST circuit 3. The serial access memory BIST circuit 3 then determines if the result signal matches an expected value. It is thereby possible to perform transaction test to check if the integrated circuit 1 operates normally at an actual operation frequency in the configuration where the memory block 10 has the combinational circuits in the previous and subsequent stages of the RAM macro 2.

Conventional test methods require a large scan pattern with use of the scan circuits 107 and 108 in order to test the combinational circuits in the vicinity of the RAM macro 2 with an actual operation clock frequency. It is thus necessary to externally input a large scan pattern by taking a long time so as to set data to the SFFs 9a. The test thereby takes a long time and it is difficult to achieve a high fault detection rate. On the other hand, this embodiment inputs to set the BIST signal from the serial access memory BIST circuit 3 to the input SFF group 9A through the selector 4. By placing the selector 4 in the middle of the scan chain, it is possible to input the data for testing the memory block 10 directly to the SFF group 9A, not through the scan input terminal 21. This enables to input and set the data for testing the memory block 10 to the input SFF group 9A with a very short time. Therefore, it is possible to test if restrictions of a setup time and a hold time are satisfied in the combinational circuits 5 and 6 placed in the vicinity of the RAM macro 2 included in the memory block 10 with a high-speed system operation frequency (actual operation frequency).

Further, since the serial access memory BIST circuit 3 automatically performs generation of the BIST signal to serve as a read/write command to the RAM macro 2 and match determination with an expected value, it is possible to perform the operation test of the memory block 10, including defect detection of the combinational circuits 5 and 6, at an actual operation clock frequency efficiently in a short time.

Furthermore, using the BIST signal eliminates the need for a large test vector, and placing the selector 4 in the immediately previous stage of the input SFF group 9A allows significant reduction of a test time compared to conventional techniques.

Although the combinational circuits are placed in the previous and subsequent stages of the RAM macro 2 of the memory block 10 in this embodiment, the present invention is not limited thereto. For example, the present invention is also applicable to the cases where the combinational circuit is placed either the previous or the subsequent stage of the RAM macro, and where the input SFF group 9A and the input of the RAM macro 2 are connected not through the combinational circuit 5 and the output of the RAM macro 2 and the output SFF group 9B are connected not through the combinational circuit 6. In these cases as well, it is possible to perform the operation test of the memory block 10 efficiently at an actual operation frequency.

### Second Embodiment

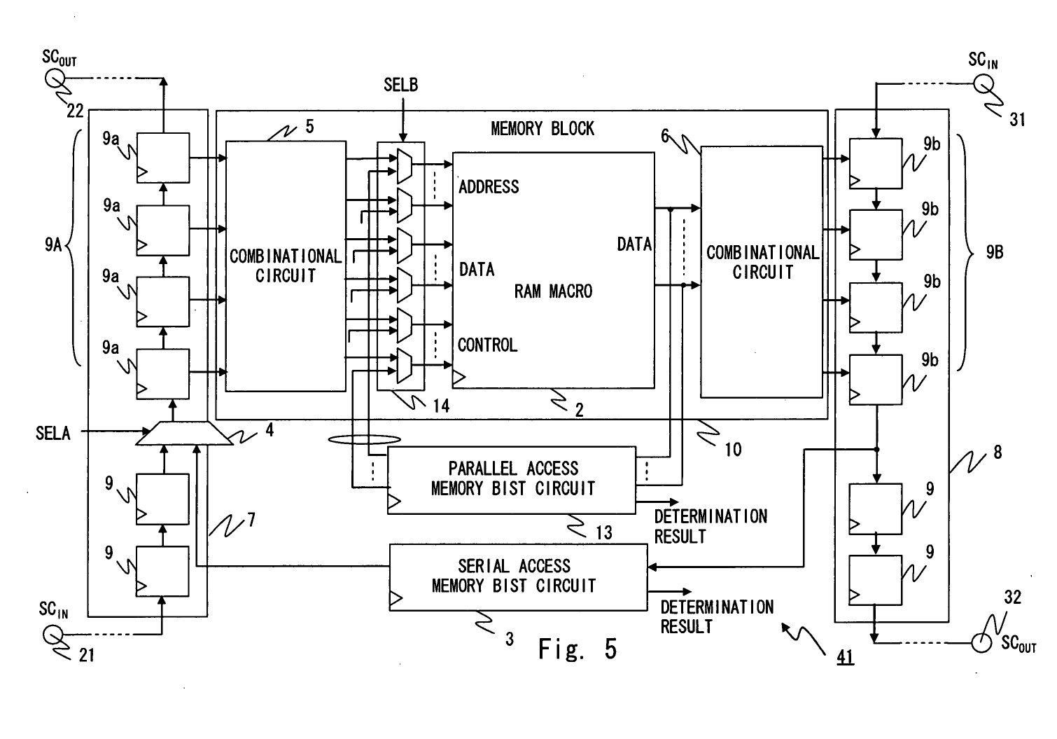

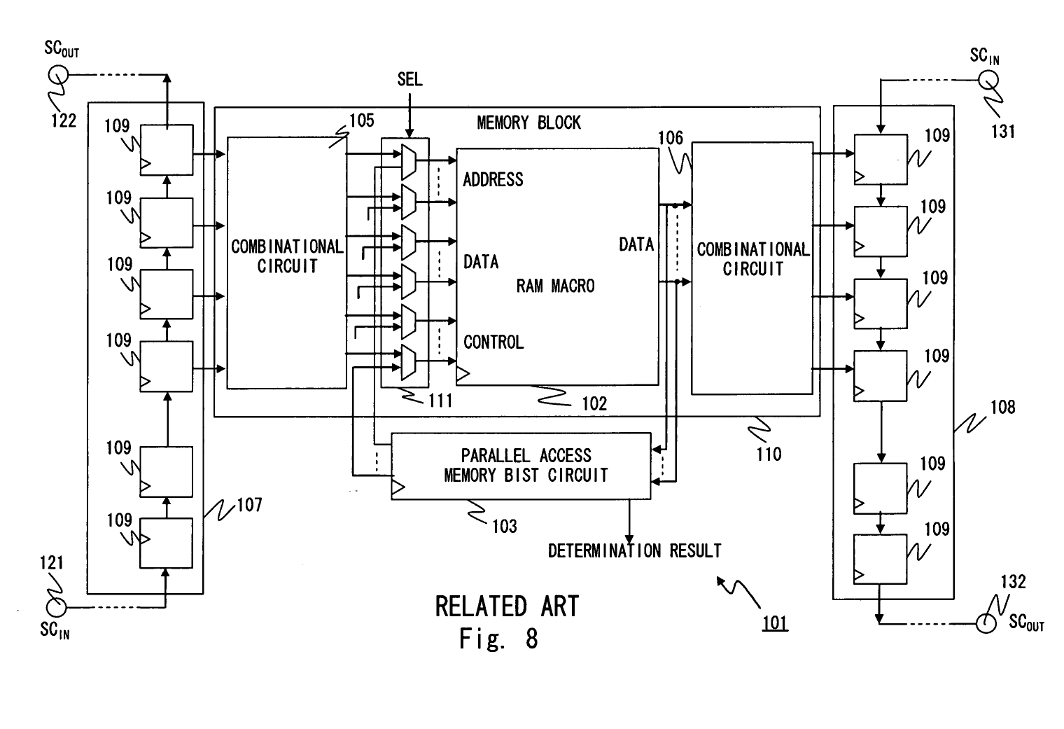

FIG. 5 is a block diagram showing an integrated circuit according to a second embodiment of the invention. An integrated circuit 41 of this embodiment has a parallel access memory BIST circuit 13 and a selector group 14 in addition to the configuration of FIG. 1. Further, it has a third test mode for performing a unit operation test of a RAM macro 2 by the parallel access memory BIST circuit in addition to the first and second test modes, just like the conventional integrated circuit 101 shown in FIG. 8. In the second embodiment of FIG. 5, the same elements as in the first embodiment of FIG. 1 are denoted by the same reference symbols and not described in detail.

In FIG. 5, the selector group 14 is composed of n number of selectors where n is an integer that correspond to the n number of input terminals of the RAM macro 2. Each selector receives a second selection signal SELB to switch an output signal between the second test mode and the third test mode. Specifically, in the second test mode, the second selection signal SELB is set to a logic value “0”, for example. In this case, the BIST signal output from the first scan circuit 7 is input to the combinational circuit 5 where logic operation is performed on the n number of signals and the selector group 14 selects and outputs them to the RAM macro 2. In the third test mode, the second selection signal SELB is set to a logic value “1”, for example. In this case, the selector goup 14 selects the n number of BIST signals generated in the parallel access memory BIST circuit 13 and outputs them to the RAM macro 2.

In the third test mode, the parallel access memory BIST circuit 13 generates a BIST signal and outputs it in parallel to the selector group 14. The selector group 14 selectively supplies the BIST signal to the RAM macro 2 so as to write test data into a specified address and then read out this data. The parallel access memory BIST circuit 13 receives the acquired test data in parallel and compares it with an expected value to see if they match.

The BIST signal generated in the parallel access memory BIST circuit 13 is a write command composed of a write address, write data (test data) and a write control signal in the write operation, while it is a read command compose of a read address and a read control signal in the read operation.

On the other hand, the BIST signal generated in the serial access memory BIST circuit 3 which is the same as the one in the first embodiment 1 is converted into a write/read command by the logic operation in the combinational circuit 5. In this case, the test data read out from the memory block 10 becomes a result signal after the logic operation in the combinational circuit 6 and input to the output SFF group 9B. Then, the serial access memory BIST circuit 3 compares the result signal, which is a value converted from the test data by the logic operation, with an expected value to see if they match.

The operations in the first test mode and the second test mode in this embodiment are the same as those in the first embodiment. The operation in the third test mode is the same as the operation test on the RAM macro by the parallel access memory BIST circuit in the conventional integrated circuit 101 shown in FIG. 8.

In the operation test on the RAM macro 2 by using the parallel access memory BIST circuit 13, the parallel access memory BIST circuit 13 generates a BIST signal composed of a write address, write data (test data) and a write control signal in a predetermined process.

The parallel access memory BIST circuit 13 then supplies this BIST signal in parallel to the RAM macro 2 through each selector of the selector group 14 in synchronization with the clock CK, thereby writing test data to the write address of the RAM macro 2.

After that, the test data is read out and compared with an expected value. For this step, the parallel access memory BIST circuit 13 again generates a BIST signal composed of a read address and a read control signal in a predetermined process. It then supplies the BIST signal to the RAM macro 2 through each selector of the selector group 14 in synchronization with the clock CK. The test data of the specified read address is thereby read out from the RAM macro 2 and supplied in parallel to the parallel access memory BIST circuit 13.

The parallel access memory BIST circuit 13 compares the acquired test data with an expected value and, if they match, it determines that the write/read operation in the RAM macro 102 is performed normally.

This embodiment has the second test mode and the third test mode to further increase the efficiency of the test on the memory block 10. For example, the third test mode performs the write/read operation test on all the addresses of the RAM macro 2 by the parallel access memory BIST circuit 13. Then, the second test mode performs the logic operation in the combinational circuits 5 and 6 and the test on a critical path in the entire memory block 10 with an actual operation clock frequency by the serial access memory BIST circuit 3. Execution of the two kinds of tests allows more efficient testing with a short time without decreasing the defect detection rate compared with the first embodiment.

Further though the parallel access memory BIST circuit 13 can generate addresses and data by using a random number generator, it may generate addresses in ascending order from the smallest address or in descending order from the largest address. Further, it may generate addresses according to predetermined algorithm or select from a plurality of address generation patterns.

Furthermore, the parallel access memory BIST circuit 3 may generate data so as to be suitable for marching test or for checkerboard test. Alternatively, it may generate data according to predetermined algorithm or select from a plurality of data generation patterns.

The parallel access memory BIST circuit 13 may perform test data writing, reading and comparison with an expected value for each address of the RAM macro 2, may write data to all test addresses and then perform reading and comparison with an expected value for each address, or may select one of these.

### Third Embodiment

The third embodiment of the invention is described hereinafter. In the second test mode in the first and second embodiments described earlier, the memory BIST circuit supplies a BIST signal through the input SFF group 9A and receives a result signal through the output SFF group 9B, thereby implementing a test of the memory block with an actual operation frequency. The test of the memory block 10 with an actual operation frequency is feasible if a test signal is transmitted through the input SFF group 9A and the output SFF group 9B. Thus, this embodiment uses a parallel access memory BIST circuit 33 instead of the serial access memory BIST circuit 3 used in the first and second embodiments so as to supply a BIST signal in parallel to the input SFF group 9A.

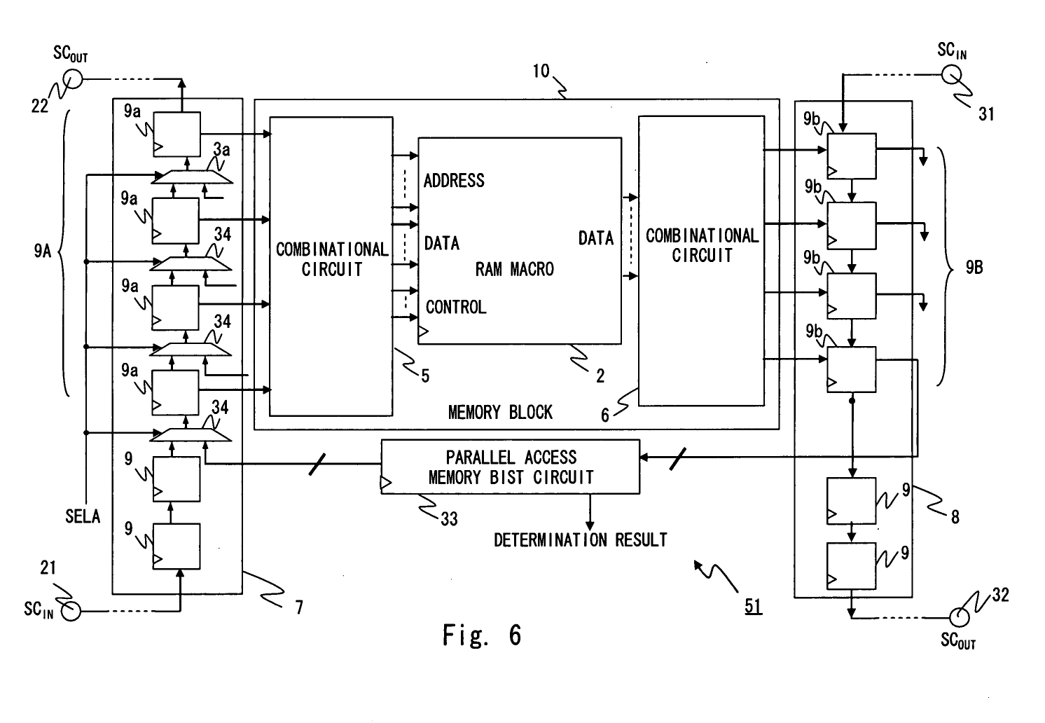

FIG. 6 is a block diagram showing an integrated circuit 51 according to the third embodiment of the invention. In the third embodiment of FIG. 6, the same elements as in the first embodiment of FIG. 1 are denoted by the same reference symbols and not described in detail. The integrated circuit 51 has the parallel access memory BIST circuit 33 that outputs a BIST signal in parallel. It further has a selector 34 in the previous stage of each SFF 9a of the input SFF group 9A. Each SFF 9a can select and supply the parallel BIST signal to the combinational circuit 5.

In the first test mode, the selector 34 selects the scan test signal from the SFF 9 or 9a in the previous stage and supplies it to the SFF 9a in the subsequent stage according to the first selection signal SELA. In the second test mode, the selector 34 selects the BIST signal from the SFF 9 or 9a in the previous stage and supplies it to the SFF 9a.

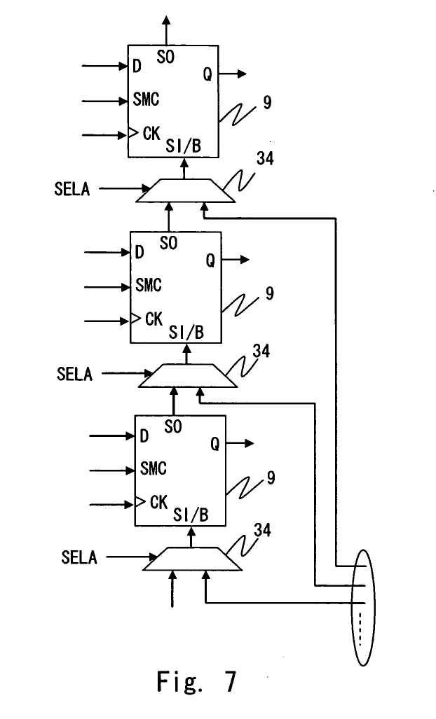

FIG. 7 shows a detail of a part of a scan chain of this embodiment. Each selector 34 is placed between the output of the SFF 9a in the previous stage and the input of the SFF 9a in the subsequent stage. The BIST signal or the scan test signal is selectively input to the SFF 9a by the selector 34, and the SFF 9a outputs the input signal.

The output SFF group 9B supplies the result signal from the combinational circuit 6 in parallel to the parallel access memory BIST circuit 33.

It is feasible to place a selector in the output of each SFF 9b. In this case, in the first test mode, the selector may select the scan test signal from the SFF 9 or 9b in the previous stage and supplies it to the SFF 9b or 9 in the subsequent stage. In the second test mode, the selector may select the result signal from the SFF 9b in the previous stage and supplies it to the parallel access memory BIST circuit 33.

Though this embodiment has the selector 34 that selects one of two inputs and outputs the selected one, it may have a selector that receives the BIST signal in parallel from the parallel access memory BIST circuit 33 and outputs it to each SFF 9a at the same time.

The integrated circuit 51 replaces the serial access memory BIST circuit 3 in the first embodiment with the parallel access memory BIST circuit 33 that outputs a BIST signal in parallel and receives a result signal in parallel. Otherwise, the integrated circuit 51 operates in the same way as the integrated circuit of the first embodiment. The SFF 9a shifts and transfers a received scan test signal to the SFF 9a in the subsequent stage in the first mode. In the second mode, the input SFF group 9A supplies the BIST signal from the parallel access memory BIST circuit 33 to the combinational circuit 5 in synchronization with the clock signal with an actual operation frequency. The combinational circuit 5 performs the logic operation on the BIST signal to convert it into a write or read command. The command is supplied to the RAM macro 2 to perform a test on the RAM macro 2. In the case of a read command, a result signal is supplied to the SFF 9b through the combinational circuit 6 and transferred in parallel to the parallel access memory BIST circuit 33, and the parallel access memory BIST circuit 33 compares the result signal with an expected value to see if they match.

This embodiment exerts the same effect as the first embodiment. Further, since the BIST signal is supplied in parallel to the input SFF group 9A, it is possible to perform the test of the memory block 2 with an actual operation frequency in a still shorter time compared to the first embodiment.

In the above embodiment, the parallel access memory BIST circuit 33 outputs the BIST signal in parallel and receives the result signal in parallel. Instead, it may output the BIST signal in parallel and receives the result signal in serial. Further, it is feasible to place a selector group between the combinational circuit 5 and the RAM macro 2 and also place a parallel access memory BIST circuit for conducting a unit BIST on a RAM macro 2 to enable the third test mode just like in the second embodiment. It is thereby possible to execute a unit BIST on the RAM macro 2 at a high speed and perform a test on the memory block 2 at an actual operation frequency. Further, the combination of these tests allows detecting if a defect occurs in the RAM macro 2 or in the combinational circuits 5 and 6.

From the invention thus described, it is obvious that the present invention is not limited to the above-described embodiments but the embodiments of the invention may be varied in many ways. For example, though the memory macro of the memory block is a RAM macro in the above embodiments, the RAM macro may be any of a SRAM macro, a DRAM macro, and a nonvolatile RAM macro. The memory macro may be a read-only ROM or the like.

Further, the SFF receives a scan clock with a lower frequency than an actual operation frequency from a clock terminal during the shift mode and receives a clock with an actual operation frequency from the clock terminal during the capture mode in the above embodiments. Alternatively, the SFF may have a scan clock terminal and a clock terminal for normal operation to receive a clock from the scan clock terminal during the shift mode and receive a clock from the normal operation clock terminal during the capture mode.

Furthermore, the SFF may use a single terminal both as the scan output terminal SO and the data output terminal Q in FIGS. 2 and 7.

It is also feasible to use a single circuit both as the serial access memory BIST circuit 3 and the parallel access memory BIST circuit 13 in FIG. 5 and switch the test function by an external test mode signal. For example, a parallel-serial converter may be placed in the output part of the serial access memory BIST circuit 3 and a serial-parallel converter may be placed in the input part. The BIST circuit may be configured so as to select whether to output the BIST signal as a parallel signal or as a serial signal by specifying a test mode externally to the serial access memory BIST circuit 3.

In this case, in the second mode, the BIST circuit may generate a parallel BIST signal to be converted into a write/read command, and the parallel-serial converter may convert the signal into a serial signal corresponding to a serial access BIST signal described above. Then, the converted serial BIST signal may be supplied to the selector connected to the input SFF group. Further, the result signal transferred serially form the memory block 10 through the combinational circuit may be compared with an expected value after being converted into a parallel signal corresponding to a parallel access BIST signal by the serial-parallel converter.

Then, in the third mode, the BIST circuit may supply the parallel signal indicating write/read information directly to the RAM macro 2 in the memory block 10 and receive the output data in parallel from the RAM macro 2 to compare it with an expected value.

If the integrated circuit has a plurality of RAM macros, for example, it is feasible to use the parallel access memory BIST circuit 3 and the parallel access memory BIST circuit 63 in combination.

It is apparent that the present invention is not limited to the above embodiment that may be modified and changed without departing from the scope and spirit of the invention.

What is claimed is:

1. An integrated circuit comprising:
a memory block including a memory macro;
a scan circuit including a plurality of scan cells forming a scan path; and
a Built-In Self Test (BIST) circuit generating a BIST signal, receiving a result signal indicating a test result of the memory block, and determining if the result signal-matches an expected value,
wherein the plurality of scan cells include an input scan cell group capable of supplying data to the memory block and an output scan cell group capable of receiving data from the memory block,
each scan cell of the input scan cell group receives a scan test signal from a scan cell of a previous stage in a first test mode and receives the BIST signal in a second test mode, and
each scan cell of the output scan cell group receives a scan test signal from a scan cell of a previous stage in the first test mode and receives the result signal from the memory block in the second test mode.

2. The integrated circuit according to claim 1, wherein the memory block further includes a combinational circuit placed between the input scan cell group and the memory macro and/or between the memory macro and the output scan cell group.

3. The integrated circuit according to claim 1, wherein
the scan circuit includes a selector placed in an earlier stage than the input scan cell group,
the BIST circuit serially outputs the BIST signal in the second test mode, and
the selector selects the scan test signal from a scan cell of a previous stage and supplies the scan test signal to a scan cell of a subsequent stage in the first test mode, and selects the BIST signal from the BIST circuit and supplies the BIST signal to a scan cell of a subsequent stage in the second test mode.

4. The integrated circuit according to claim 1, wherein the scan circuit includes a first scan circuit having the input scan cell group and a second scan circuit having the output scan cell group.

5. The integrated circuit according to claim 2, wherein
the scan circuit includes a selector placed in an earlier stage than the input scan cell group,
the BIST circuit serially outputs the BIST signal in the second test mode, and
the selector selects the scan test signal from a scan cell of a previous stage and supplies the scan test signal to a scan cell of a subsequent stage in the first test mode, and selects the BIST signal from the BIST circuit and supplies the BIST signal to a scan cell of a subsequent stage in the second test mode.

6. The integrated circuit according to claim 3, further comprising:
a first combinational circuit between the input scan cell group and the memory macro,
wherein the selector supplies the BIST signal to the input scan cell group in the second test mode.

7. The integrated circuit according to claim 3, further comprising:
a second combinational circuit between the output scan cell group and the memory macro.

8. The integrated circuit according to claim 3, wherein the BIST circuit is connected to an output of the output scan cell group and receives the result signal by shift operation of the output scan cell group.

9. The integrated circuit according to claim 3, wherein, in the second test mode, the input scan cell group supplies the BIST signal to the memory block in synchronization with a clock of an actual operation frequency, and the output scan cell group receives the result signal from the memory block in synchronization with a clock of an actual operation frequency.

10. The integrated circuit according to claim 9, wherein
the first scan circuit temporarily stores a write BIST signal for writing test data to the memory macro into the input scan cell group, supplies the write BIST signal to the memory macro in synchronization with a clock of an actual operation frequency, temporarily stores a read BIST signal for reading the test data from the memory macro into the input scan cell group, and supplies the read BIST signal to the memory macro in synchronization with a clock of an actual operation frequency, and the second scan circuit temporarily stores the test data read out from the memory macro in synchronization with the clock of the actual operation frequency and transmits the test data to the BIST circuit by shift operation.

11. The integrated circuit according to claim 1, further comprising:
a second selector placed in an input side of the memory macro,
wherein the BIST circuit generates a first BIST signal to be supplied to the input scan cell group and a second BIST signal to be supplied to the memory macro, and
the second selector selects and supplies data from the input scan cell group to the memory macro in the second test mode, and selects and supplies the second BIST signal to the memory macro in a third test mode.

12. The integrated circuit according to claim 1, further comprising:
a second selector placed in an input side of the memory macro, and
wherein the BIST circuit including a first BIST circuit supplying a first BIST signal to the input scan cell group and a second BIST circuit supplying a second BIST signal to the memory macro, and
the second selector selects and supplies data from the input scan cell group to the memory macro in the second test mode, and selects and supplies data from the second BIST circuit to the memory macro in a third test mode.

13. The integrated circuit according to claim 10, wherein the second selector comprises n-number of selectors corresponding to input terminals of the memory macro and receives the second BIST signal from the second BIST circuit in parallel.
